(19) United States
(12) Patent Application Publication
(10) Pub. No.: US 2010/0181060 A1
(43) Pub. Date: Jul. 22, 2010

(54) HEAT RADIATOR OF SEMICONDUCTOR PACKAGE

(75) Inventor: Suguru KOBAYASHI, Nagano-shi (JP)

Correspondence Address: IPUSA, P.L.L.C, 1054 31ST STREET, N.W., Suite 400, Washington, DC, 20007, US

(73) Assignee: SHINKO ELECTRIC INDUSTRIES CO., LTD.

(21) Appl. No.: 12/631,995

(22) Filed: Dec. 7, 2009

(30) Foreign Application Priority Data
Jan. 22, 2009 (JP) NO. 2009-012270

(51) Int. Cl. H01L 23/373; F28F 21/02

(52) U.S. Cl. 165/185

(57) ABSTRACT

A heat radiator of a semiconductor package, the heat radiator being provided on the semiconductor package, the heat radiator contacting a thermal interface material, the heat radiator includes a line state high thermal interface material standing, in a thermally conductive direction, on a surface of the heat radiator facing the thermal interface material. Head end parts of the line state high thermal interface material are adhered to a surface of the thermal interface material.

### CROSS-REFERENCE TO RELATED APPLICATIONS

This patent application is based upon and claims the benefit of priority of Japanese Patent Application No. 2009-012270 filed on Jan. 22, 2009 the entire contents of which are incorporated herein by reference.

### BACKGROUND OF THE INVENTION

1. Field of the Invention

The present invention generally relates to heat radiators of semiconductor packages. More specifically, the present invention relates to a heat radiator of a semiconductor package, the heat radiator being provided on the semiconductor package, the heat radiator contacting a thermal interface material.

2. Description of the Related Art

A semiconductor element used for, for example, a CPU (Central Processing Unit) is electrically connected on and fixed to a package. At the time of operation, a temperature of the semiconductor element becomes high. Therefore, unless the temperature of the semiconductor element is forcibly decreased, capacities of the semiconductor element do not work so that the semiconductor element may be damaged. Accordingly, a path for effectively radiating heat generated by the semiconductor element to an outside is secured by mounting a heat radiation plate (heat sink) or a heat radiation fin (heat pipe) on the semiconductor element. A TIM (thermal interface material) is sandwiched between the semiconductor element and the heat radiation plate or the like. Following concave and convex surfaces of the semiconductor element and the heat radiation plate or the like, contact thermal resistance is reduced so that a smooth thermal conductance is attempted.

FIG. 1 is a cross-sectional view showing an example where a related art heat radiator is provided on a semiconductor package. In this semiconductor package, heat generated from a semiconductor element 200 mounted on a wiring board 100 is transferred to a heat radiation plate 400 via a thermal interface material 300 provided on the semiconductor element 200. In addition, the heat transferred to the heat radiation plate 400 is transferred to a heat radiation fin 500 via the thermal interface material 300 provided on the heat radiation plate 400.

Thus, the thermal interface material 300 thermally connects the semiconductor element 200 and the heat radiation plate 400 to each other without their directly coming in contact with each other. In addition, the thermal interface material 300 thermally connects the heat radiation plate 400 and the heat radiation fin 500 to each other without their directly coming in contact with each other.

Since indium has a high thermal conductivity, indium is frequently used as a material of the thermal interface material 300. However, since indium is a rare metal, indium is expensive and a sufficient supply of indium may not be expected in the future. Furthermore, a thermal process such as reflow is required for adhering the thermal interface material 300 to the heat radiation plate 400. Therefore, a manufacturing process is complicated.

Because of this, silicon grease, an organic resin binder including graphite or a metal filler as a high thermal interface material, or the like is used as another example of the thermal interface material 300. In addition, as the thermal interface material 300, a sheet state thermal interface material where carbon nano tubes are arranged in a thermally conductive direction, the thermal interface material being molded by resin, is known.

See, for example, Japanese Laid-Open Patent Application Publication No. 2005-347500, Japanese Laid-Open Patent Application Publication No. 2004-349497, and Japanese Laid-Open Patent Application Publication No. 2008-205273.

However, the thermal interface material 300 made by molding the high thermal interface material such as the metal filler or graphite using the resin as a binder has a problem in terms of heat radiation capacities because the thermal conductivity of the resin is not high. In addition, the carbon nano tubes arranged in the thermally conductive direction have a problem where contact thermal resistance between carbon nano tube end surfaces and the heat radiator is large and therefore expected capacities cannot be achieved. This is because short carbon nano tubes cannot reach a surface of the heat radiator.

FIG. 2 is a cross-sectional view showing a contact surface of a thermal interface material including a high thermal interface material and the related art heat radiator. As shown in FIG. 2, seen in a micro manner, the contact surface between the heat radiation plate 400 or the heat radiation fin 500 (the heat radiation plate 400 is shown as an example) and the thermal interface material 300 becomes rough and therefore a space 600 is formed between the heat radiation plate 400 and the thermal interface material 300. In addition, an outermost layer of the thermal interface material 300 is covered with a low thermal interface material layer 301 having a high ratio of resin contained in the low thermal interface material layer 301.

Accordingly, there is no physical contact between the heat radiation plate 400 and a high thermal interface material 302 such as the metal filler or graphite and the contact thermal resistance between the heat radiation plate 400 and the high thermal interface material 302 is large. Hence, the thermal conductivity is low and the heat radiation capacities are not good.

### SUMMARY OF THE INVENTION

Accordingly, embodiments of the present invention may provide a novel and useful heat radiator of a semiconductor package solving one or more of the problems discussed above.

More specifically, the embodiments of the present invention may provide a heat radiator of a semiconductor package, the heat radiator having a high thermal conductivity and good radiating abilities.

Another aspect of the embodiments of the present invention may be to provide a heat radiator of a semiconductor package, the heat radiator being provided on the semiconductor package, the heat radiator contacting a thermal interface material, the heat radiator including a line state high thermal interface material standing, in a thermally conductive direction, on a surface of the heat radiator facing the thermal interface material, wherein head end parts of the line state high thermal interface material are adhered to a surface of the thermal interface material.

Another aspect of the embodiments of the present invention may be to provide a heat radiator of a semiconductor package, the heat radiator being provided on the semiconductor package, the heat radiator contacting a thermal interface material, the heat radiator including: a first line state high thermal interface material standing, in a thermally conductive direction, on a surface of the heat radiator facing the thermal interface material; a second line state high thermal interface material standing, in a thermally conductive direction, on a surface of the thermal interface material facing the heat radiator, wherein the head end of the first line state high thermal interface material is positioned in a space formed by the neighboring second line state high thermal interface material, and the head end of the second line state high thermal interface material is positioned in a space formed by the neighboring first line state high thermal interface material, so that the head end of the first line state high thermal interface material and the head end of the second line state high thermal interface material are adhered to each other.

According to the embodiments of the present invention, it is possible to provide a heat radiator of a semiconductor package, the heat radiator having a high thermal conductivity and good radiating abilities.

Additional objects and advantages of the embodiments are set forth in part in the description which follows, and in part will become obvious from the description, or may be learned by practice of the invention. The object and advantages of the invention will be realized and attained by means of the elements and combinations particularly pointed out in the appended claims. It is to be understood that both the foregoing general description and the following detailed description are exemplary and explanatory and are not restrictive of the invention as claimed.

### BRIEF DESCRIPTION OF THE DRAWINGS

FIG. 1 is a cross-sectional view showing an example where a related art heat radiator is provided on a semiconductor package;

FIG. 2 is a cross-sectional view showing a contact surface of a thermal interface material including a high thermal interface material and the related art heat radiator;

FIG. 3 is a cross-sectional view showing a heat radiation plate and a heat radiation fin of a first embodiment of the present invention provided on a semiconductor package;

FIG. 4 is a cross-sectional view of a TIM made of a low thermal interface material layer and a high thermal interface material layer;

FIG. 5 is an expanded cross-sectional view of carbon nano tubes formed on the heat radiation plate or the heat radiation fin;

FIG. 6 is an expanded cross-sectional view of a contact part of the heat radiation plate or the heat radiation fin and the TIM;

FIG. 7 is a flowchart showing a manufacturing process of a heat radiator of a semiconductor package;

FIG. 8 is a view showing an attaching process of the heat radiator of the semiconductor package;

FIG. 9 is a flowchart showing a semiconductor package mounting process;

FIG. 10 is a view showing a TIM where a pillar such as metal or carbon pierces a resin sheet;

FIG. 11 is an expanded cross-sectional view of a contact part of the heat radiation plate or the heat radiation fin shown in FIG. 5 and the TIM shown in FIG. 10;

FIG. 12 is a cross-sectional view of a sheet state TIM molded by resin, the TIM having carbon nano tubes arranged in a thermally conductive direction; and

FIG. 13 is an expanded cross-sectional view of a contact part of the heat radiation plate or the heat radiation fin and the TIM shown in FIG. 12.

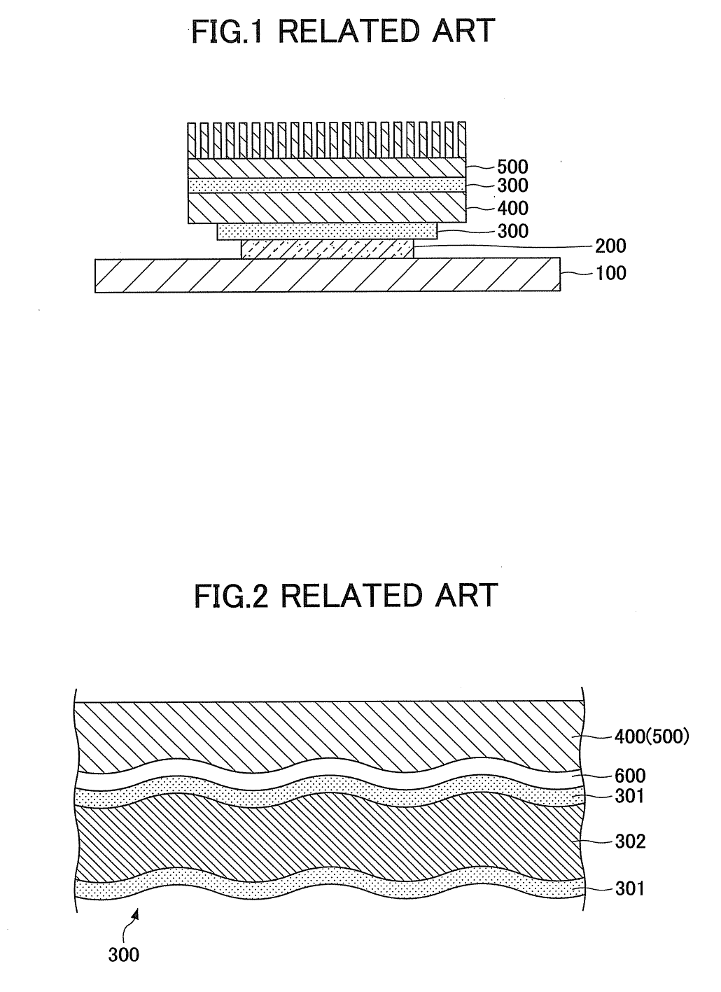

### DETAILED DESCRIPTION OF THE PREFERRED EMBODIMENTS

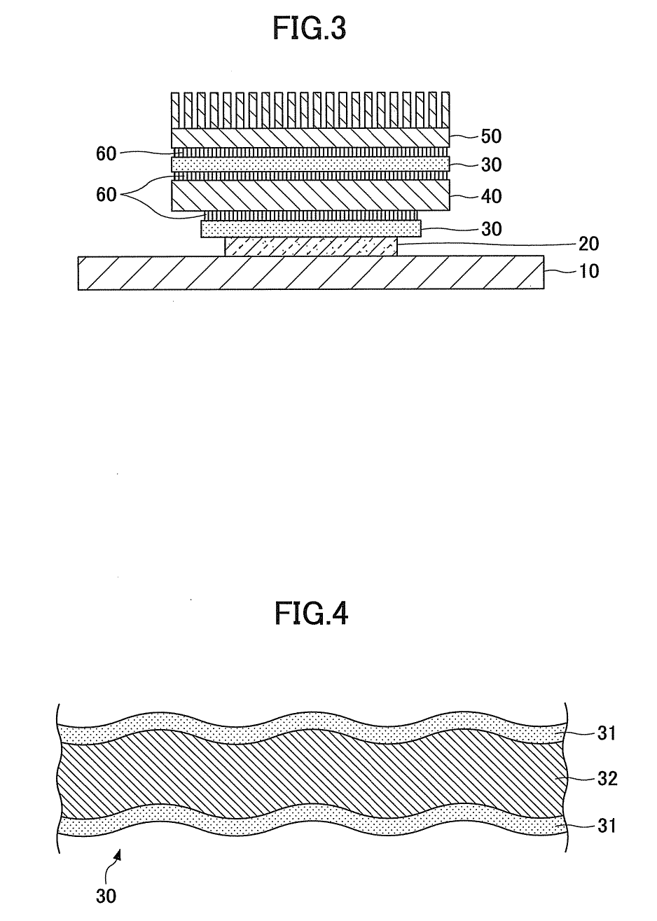

A description is given below, with reference to the FIG. 3 through FIG. 13 of embodiments of the present invention.

### FIRST EMBODIMENT

### Heat Radiator of Semiconductor Package of the First Embodiment

FIG. 3 is a cross-sectional view showing a heat radiation plate and a heat radiation fin of a first embodiment of the present invention provided on a semiconductor package. As shown in FIG. 3, a heat radiation plate 40 of the first embodiment of the present invention is provided on an upper surface of a TIM 30 as a thermal interface material. The TIM 30 is provided on an upper surface of a semiconductor element 20. The semiconductor element 20 is provided on a board 10. In addition, a heat radiation fin 50 is provided on an upper surface of another TIM 30. This TIM 30 is provided on the upper surface of the heat radiation plate 40.

The TIM 30 contains a high thermal interface material such as a metal filler, a carbon filler, graphite, or carbon nano tubes. The TIM 30 is molded by using epoxy resin or organic resin as a main ingredient.

By providing the TIM 30 between the semiconductor element 20 and the heat radiation plate 40, the semiconductor element 20 and the heat radiation plate 40 are thermally connected to each other. In addition, by providing the TIM 30 between the heat radiation plate 40 and the heat radiation fin 50, the heat radiation plate 40 and the heat radiation fin 50 are thermally connected to each other.

The heat radiation plate 40 may be, for example, a heat sink or the like. The heat radiation fin 50 may be, for example, a heat radiation fin having a heat pipe. The heat radiation plate 40 and the heat radiation fin 50 are made of a material having a high thermal conductive ratio such as oxygen-free copper where nickel plating is applied or aluminum. Heat generated from the semiconductor. element 20 is radiated to an outside by the heat radiation plate 40 or the heat radiation fin 50. The thickness of the heat radiation plate may be, for example, approximately 0.5 mm through approximately 2 mm.

As shown in FIG. 3, line state carbon nano tubes 60 made of the high thermal interface material stand on a surface of the heat radiation plate 40 or the heat radiation fin 50 facing the TIM 30 in a thermally conductive direction, namely a direction perpendicular to the surface of the heat radiation plate 40 or the heat radiation fin 50 facing the TIM 30. Although the carbon nano tubes 60 are formed on upper and lower surfaces of the heat radiation plate 40 in the first embodiment of the present invention, a place where the carbon nano tubes 60 are formed is not limited to both surfaces of the heat radiation plate 40.

FIG. 4 is a cross-sectional view of the TIM 30 made of a low thermal interface material layer 31 and a high thermal interface material layer 32. As shown in FIG. 4, the outermost surface of the TIM 30 is covered with the low thermal interface material layer 31 and the high thermal interface material layer 32 is included inside the TIM 30.

The low thermal interface material layer 31 has a high ratio of resin contained in the low thermal interface material layer 31. A slight amount of the high thermal interface material 32 such as the metal filler is contained in the low thermal interface material layer 31 and therefore the thermal conductivity of the low thermal interface material layer 31 is low.

The high thermal interface material 32 includes at least one of a material selected from a group consisting of, for example, a metal filler which is conductive metal, a carbon filler, graphite, and carbon nano tubes. These materials are provided in the high thermal interface material 32 in close formation. Hence, the thermal conductivity of the high thermal interface material 32 is high. The entire thickness of the TIM may be, for example, approximately 0.25 mm. The thickness of the low thermal interface material layer 31 may be, for example, approximately 4 μm through approximately 5 μm.

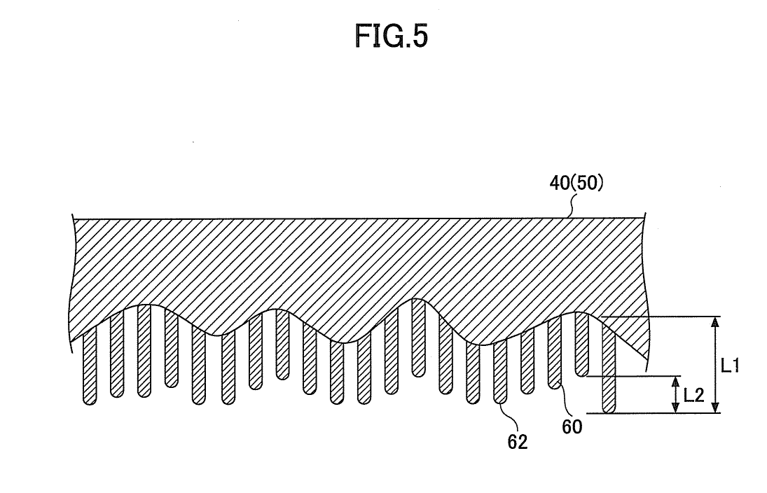

FIG. 5 is an expanded cross-sectional view of carbon nano tubes formed on the heat radiation plate or the heat radiation fin. As shown in FIG. 5, the carbon nano tubes 60 stand on a surface of the heat radiation plate 40 or the heat radiation fin 50 facing the TIM 30 in a thermally conductive direction, namely a direction perpendicular to the surface of the heat radiation plate 40 or the heat radiation fin 50 and facing the TIM 30.

The carbon nano tubes 60 are crystals of carbon and have a substantially cylindrical-shaped (line state) configuration where a diameter may be, for example, approximately 0.7 nm through approximately 70 nm. Thermal conductivity of the carbon nano tubes 60 is high and the coefficient of thermal conductivity of the carbon nano tubes 60 may be, for example, approximately 3000 W/(m·K). In other words, the carbon nano tubes 60 are a line state high thermal interface material.

A height L1 between the surface of the heat radiation plate 40 or the heat radiation fin 50 facing the TIM 30 and the head end parts 62 of the carbon nano tubes 60 can be, for example, approximately 50 μm through approximately 100 μm. Positions of the head end parts 62 of the carbon nano tubes 60 have designated unevenness. A relative difference L2 of positions of the head end parts 62 between the shortest carbon nano tube 60 and the longest carbon nano tube 60 may be, for example, approximately 20 μm.

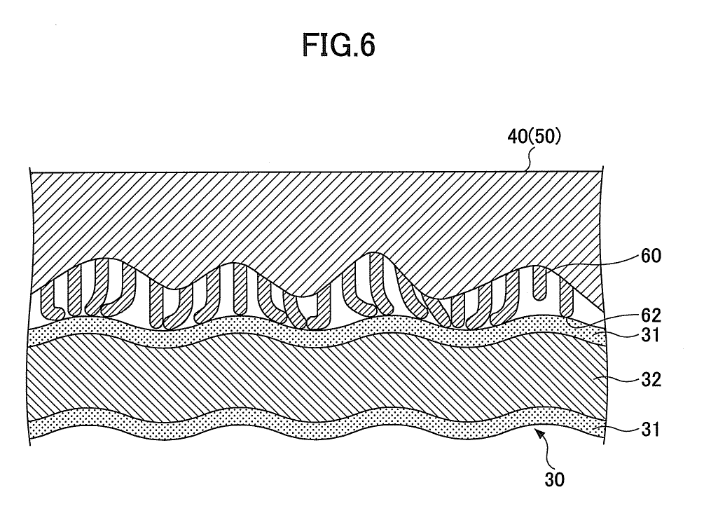

FIG. 6 is an expanded cross-sectional view of a contact part of the heat radiation plate or the heat radiation fin and the TIM. Since the carbon nano tube 60 has bending capabilities, when the carbon nano tubes 60 are provided on the surface of the TIM 30 and pressed in the thermal conductive direction as shown in FIG. 6, the head end parts 62 of the carbon nano tubes 60 are deformed in various directions. Therefore, a rate where the carbon nano tubes 60 come in contact with the low thermal interface material layer 31 which is the outermost layer of the TIM 30 can be improved. As a result of this, since the carbon nano tubes 60 are adhered to the low thermal interface material layer 31 which is the outermost layer of the TIM 30, the contact thermal resistance can be reduced so that the thermal conductivity can be improved.

In addition, the contact thermal resistance can be reduced without depending on a surface configuration (concavities and convexities of the surface) of the heat radiation plate 40, the heat radiation fin 50 or the TIM 30 and thereby the adhesion capabilities can be improved.

### Manufacturing Method of the Heat Radiator of the Semiconductor Package of the First Embodiment

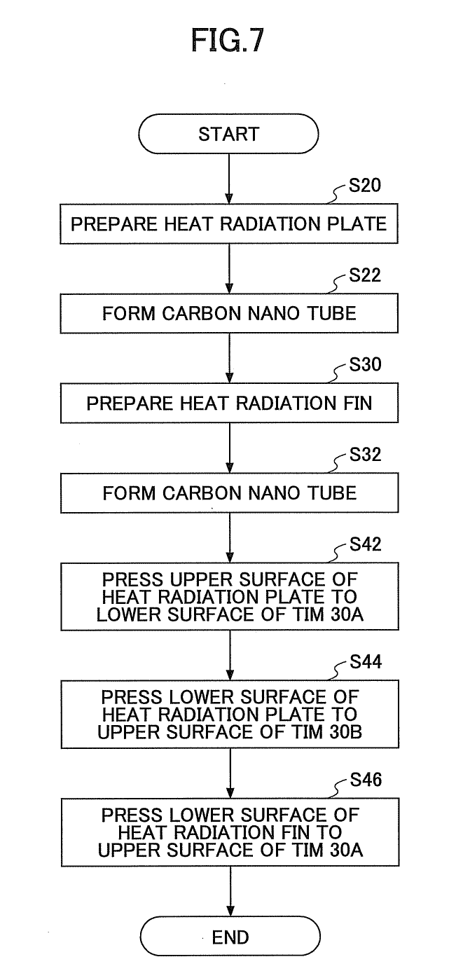

Next, a manufacturing method of the above-discussed heat radiation plate 40 and the heat radiation fin 50 is discussed with reference to FIG. 7 through FIG. 9.

FIG. 7 is a flowchart showing a manufacturing process of the heat radiator of the semiconductor package. As shown in FIG. 7, first, the carbon nano tubes 60 are formed on the heat radiation plate 40 (S20 through S22). In step S20, the heat radiation plate 40 where, for example, Ni plating is applied to oxygen-free copper is prepared. Although the material of the heat radiation plate 40 is not limited to oxygen-free copper, the carbon nano tubes 60 can be well grown by using a material whose main ingredient is oxygen-free copper as the material of the heat radiation plate 40.

Next, in step S22, the carbon nano tubes 60 are formed by a CVD (Chemical Vapor Deposition) method so as to stand on a surface of the heat radiation plate 40 facing the TIM 30 in a thermally conductive direction, namely a direction perpendicular to the surface of the heat radiation plate 40 facing the TIM 30.

More specifically, first, a metal catalyst layer is formed, by a sputtering method or the like, on the surface of the heat radiation plate 40 facing the TIM 30. For example, Fe, Co, Ni or the like can be used as a material of the metal catalyst layer. The thickness of the metal catalyst layer can be, for example, several nm (nanometers).

Next, the heat radiation plate 40 where the metal catalyst layer is formed is placed in a heating oven whose pressure and temperature are adjusted to designated values, so that the carbon nano tubes 60 are formed on the metal catalyst by the CVD (Chemical Vapor Deposition) method. The pressure of the heating oven can be, for example, approximately 100 Pa and the temperature of the heating oven can be, for example, approximately 600° C. In addition, for example, acetylene gas or the like can be used as process gas and, for example, argon gas or oxygen gas can be used as carrier gas.

The carbon nano tubes 60 are formed on the metal catalyst in the direction perpendicular to the surface of the heat radiation plate 40 facing the TIM 30. The height L1 between the surface of the heat radiation plate 40 facing the TIM 30 and the head end parts 62 of the carbon nano tubes 60 can be controlled by a growth time of the carbon nano tubes 60. In the first embodiment of the present invention, the carbon nano tubes 60 are formed on the upper and lower surfaces of the heat radiation plate 40.

Next, the carbon nano tubes 60 are formed on the heat radiation fin 50 as well as the heat radiation plate 40. A process for forming the carbon nano tubes 60 on the heat radiation fin 50 (S30 and S32 shown in FIG. 7) is discussed.

In step S30, the heat radiation fin 50 having a high thermal conductive ratio and made of, for example, aluminum, is prepared. A heat pipe may be attached to the heat radiation fin 50. Next, in step S32, the carbon nano tubes 60 are formed by the CVD (Chemical Vapor Deposition) method so as to stand on a surface of the heat radiation fin 50 facing the TIM 30 in a thermally conductive direction, namely a direction perpendicular to the surface of the heat radiation fin 50 facing the TIM 30. Details of this method are the same as ones discussed above. Thus, the carbon nano tubes 60 are formed on the heat radiation fin 50. These steps (S30 through S32) can be performed at the same time as or separated, in advance, from the steps (S20 through S22) for forming the carbon nano tubes 60 on the heat radiation plate 40.

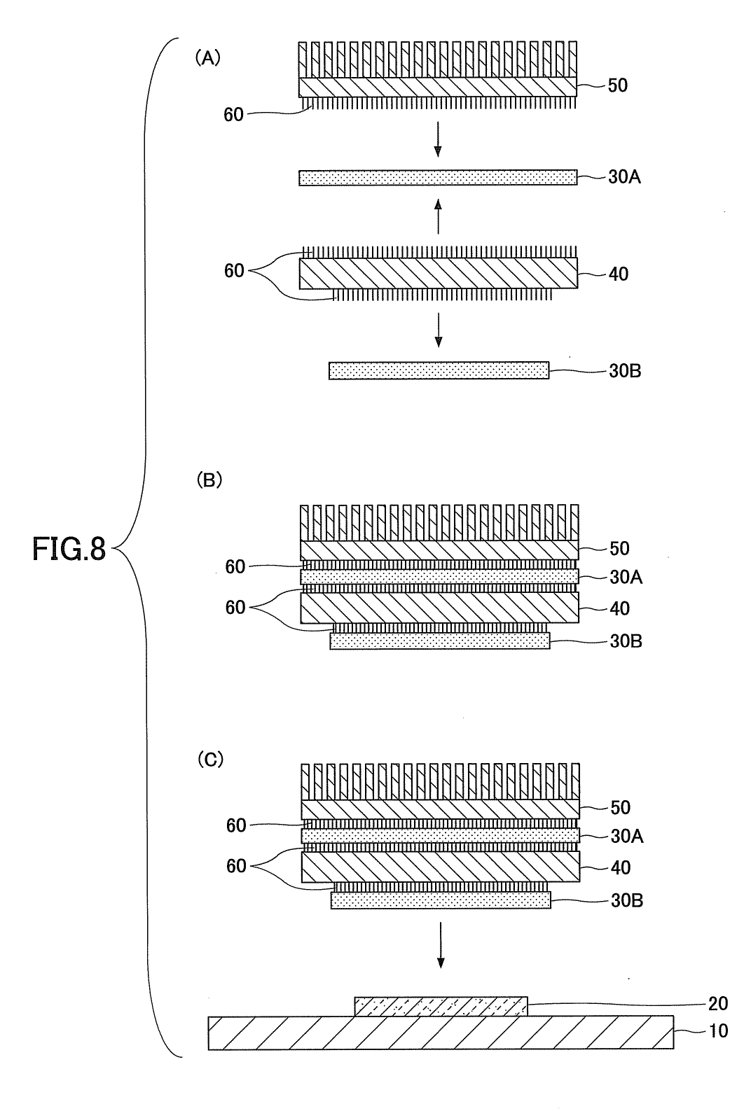

Next, a process is described for attaching the heat radiation plate 40 and the heat radiation fin 50, where the carbon nano tubes 60 (S42 through S46 shown in FIG. 7) are formed, to the TIM 30 with reference to FIG. 8. FIG. 8 is a view showing an attaching process of the heat radiator of the semiconductor package. Here, two TIMs 30, namely TIM 30A and TIM 30B, are prepared.

In step S42, the TIM 30A and the heat radiation plate 40 are prepared. As shown in FIG. 8(A), the carbon nano tubes 60 formed on the upper surface of the heat radiation plate 40 are pressed to the lower surface of the TIM 30A. Next, in step S44, the carbon nano tubes 60 formed on the lower surface of the heat radiation plate 40 are pressed to the upper surface of the TIM 30B.

Next, in step S46, the heat radiation fin 50 is prepared. As shown in FIG. 8(A), the carbon nano tubes 60 formed on the lower surface of the heat radiation fin 50 are pressed to the upper surface of the TIM 30A. As a result of this, as shown in FIG. 8(B), the heat radiation plate 40 and the heat radiation fin 50 are attached to the TIM 30A and TIM 30B.

In steps S42 through S46, applied pressure is, for example, approximately 0.5 MPa through approximately 5 MPa. By this pressure, the head end parts 62 of the carbon nano tubes 60 having bending capacities come in contact with the low thermal interface layer 31 so as to be deformed in various directions.

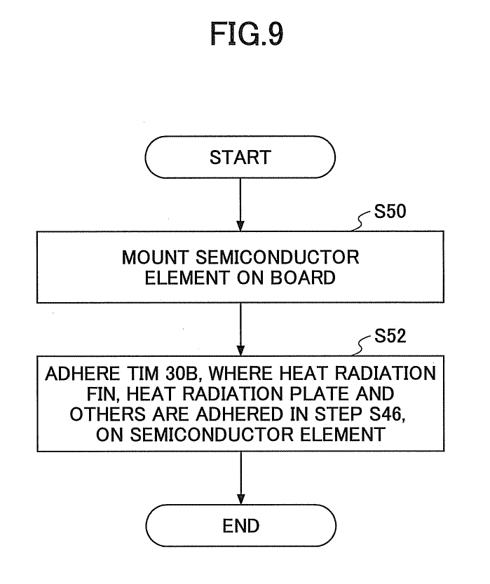

Next, a semiconductor package mounting process is discussed with reference to FIG. 8(C) which is a view showing the heat radiator being adhered. FIG. 9 is a flowchart showing a semiconductor package mounting process. As shown in FIG. 9, in step S50, the semiconductor element 20 is mounted on the board 10. Here, after being arranged on the board 10, the semiconductor element 20 is adhered and fixed to the board 10 by a known method.

Next, in step S52, the heat radiator manufactured by a heat radiator manufacturing step shown in step S46 is adhered to the semiconductor element 20. More specifically, as shown in FIG. 8(C), the lower surface of the TIM 30B where the heat radiation fin 50, the TIM 30A, and the heat radiation plate 40 are adhered in step S46, is adhered to the upper surface of the semiconductor element 20 mounted, in step S50, on the board 10.

Thus, the semiconductor package shown in FIG. 3 is completed. In the meantime, the order of the above-discussed processes can be properly changed. For example, after the lower surface of the TIM 30B where the heat radiation plate 40 is attached is adhered to the upper surface of the semiconductor element 2, the lower surface of the TIM 30A may be attached to the upper surface of the heat radiation plate 40 and the heat radiation fin 50 may be attached to the upper surface of the TIM 30A.

As discussed above, in the first embodiment of the present invention, the line state carbon nano tubes 60 made of the high thermal interface material stand on a surface of the heat radiation plate 40 or the heat radiation fin 50 facing the TIM 30 in a thermally conductive direction, namely a direction perpendicular to the surface of the heat radiation plate 40 or the heat radiation fin 50 facing the TIM 30. As a result of this, when the carbon nano tubes 60 are arranged on the surface of the TIM 30 and pressed in the thermally conductive direction, the head end parts 62 of the carbon nano tubes 60 are moved in various directions. Hence, it is possible to improve the likelihood that the carbon nano tubes 60 come in contact with the low thermal interface material layer 31 situated at the outermost surface of the TIM 30. Hence, the carbon nano tubes 60 are adhered to the low thermal interface material layer 31 situated at the outermost surface of the TIM 30. It is possible to reduce the contact thermal resistance so that the thermal conductivity can be improved. Accordingly, it is possible to improve the heat radiation capabilities whereby the heat generated from the semiconductor element 20 is radiated to an outside.

In addition, the contact thermal resistance can be reduced without depending on a surface configuration (concavities and convexities of the surface) of the heat radiation plate 40, the heat radiation fin 50 or the TIM 30 and thereby the adhesion capabilities can be improved.

### Modified Example 1 of Heat Radiator of Semiconductor Package

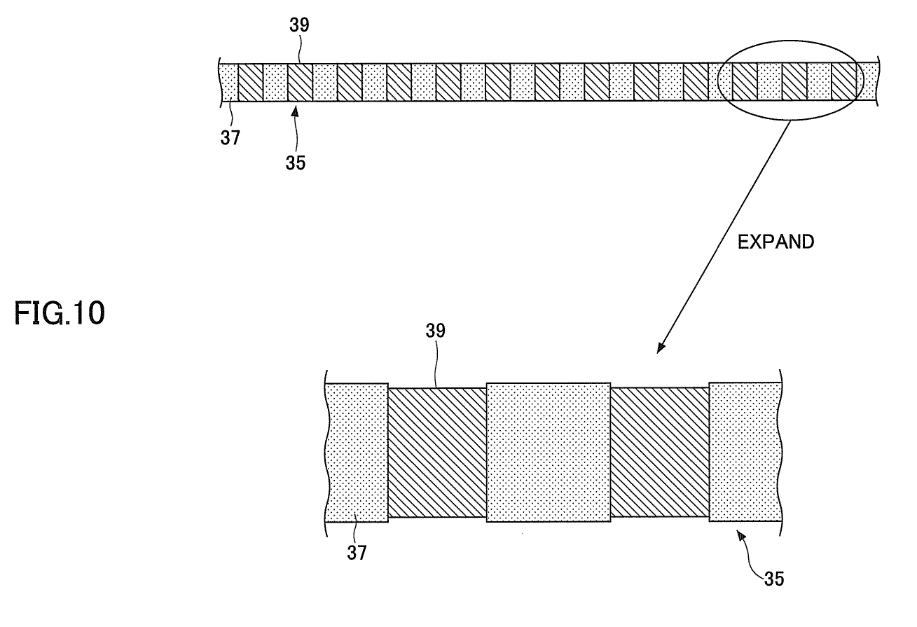

FIG. 10 is a view showing a TIM where a pillar such as metal or carbon pierces a resin sheet. As shown in FIG. 10, the TIM 35 is a sheet where a pillar such as metal or carbon pierces a resin sheet 37.

As shown in expanded view in FIG. 10, a position of a horizontal surface of the high thermal interface is slightly lower than a position of resin surface of the resin sheet 37, so that a hollow space is formed. Because of this, if the related art heat radiation plate is used in this case, an air layer is formed at the contact surface of the heat radiation plate and the TIM 35 so that the contact thermal resistance is increased and the thermal conductivity is reduced.

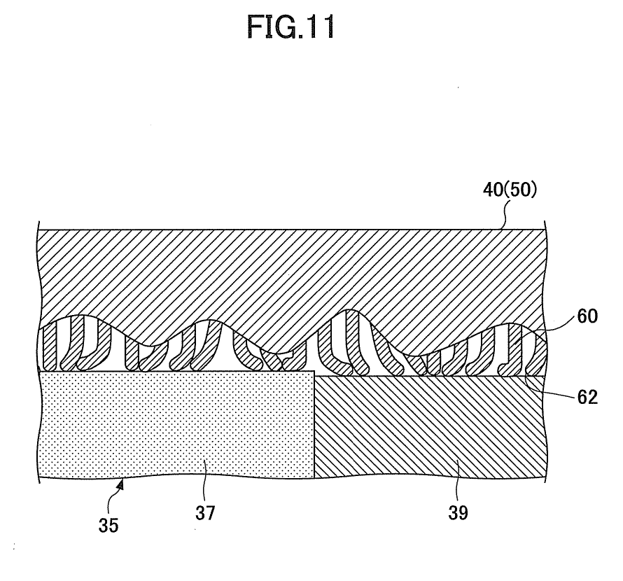

FIG. 11 is an expanded cross-sectional view of a contact part of the heat radiation plate or the heat radiation fin shown in FIG. 5 and the TIM shown in FIG. 10. As shown in FIG. 11, the carbon nano tubes 60 are formed on the surface of the heat radiation plate 40 or the heat radiation fin 50 facing the TIM 35. When the carbon nano tubes 60 arranged on the surface of the TIM 35 are pressed in the thermally conductive direction, the head end parts 62 of the carbon nano tubes 60 are moved in various directions. Hence, since even if the position of the horizontal surface of the high thermal interface is lower than the position of the resin surface of the resin sheet 37, the carbon nano tubes 60 come in contact with the entire surface of the TIM 35. As a result of this, it is possible to reduce the contact thermal resistance between the heat radiation plate 40 or the heat radiation fin 50 and the TIM 35 so that the thermal conductivity can be increased. Accordingly, it is possible to improve heat radiating abilities where the heat generated from the semiconductor element 20 is radiated to an outside.

### SECOND EMBODIMENT

### Heat Radiator of Semiconductor Package of the Second Embodiment

In the second embodiment of the present invention, a TIM 70, instead of the TIM 30 of the first embodiment shown in FIG. 3, is used. Other than this, the second embodiment is the same as the first embodiment. Only parts different from the first embodiment are discusses below.

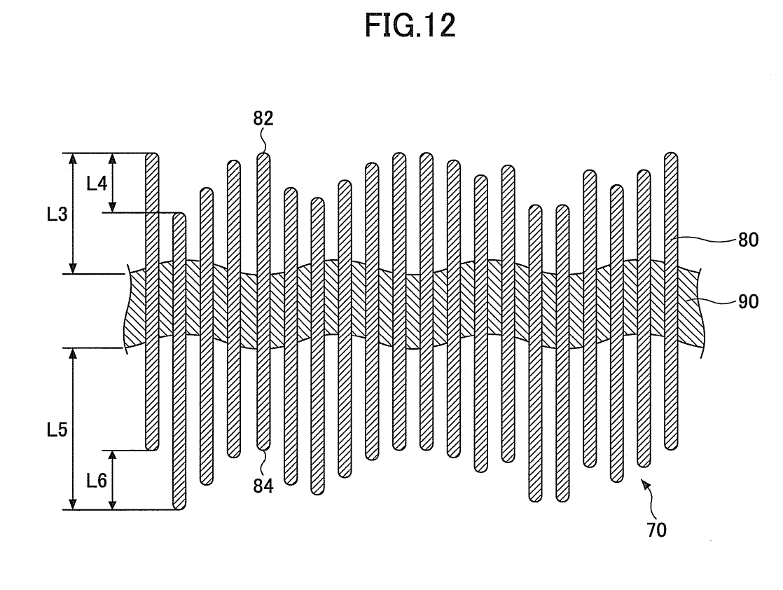

FIG. 12 is a cross-sectional view of a sheet state TIM molded by resin, the TIM having carbon nano tubes arranged in a thermally conductive direction. As shown in FIG. 12, a TIM 70 has a structure where carbon nano tubes 80 arranged in the thermal conductive direction are molded by resin 80 so that a sheet state is formed. First end parts 82 of the carbon nano tubes 80 project from one surface of the resin 90. Other end parts 84 of the carbon nano tubes 80 project from another surface of the resin 90. The carbon nano tubes 80 correspond to the high thermal interface material 32 of the TIM 30 shown in FIG. 4. The resin 90 is molded by using epoxy resin or organic resin as a main ingredient. Since details of the carbon nano tubes 80 are the same as those of the carbon nano tubes 90, explanation thereof is omitted. It is possible to make the carbon nano tubes 80 project from only one of the surfaces of the resin 90.

The height L3 between one of the surfaces of the resin 90 and the first end parts 82 of the carbon nano tubes 80 can be, for example, approximately 50 μm through approximately 100 μm. Positions of the head end parts 82 of the carbon nano tubes 80 have a designated unevenness. A relative difference L4 of positions of the head end parts 82 between the shortest carbon nano tube 80 and the longest carbon nano tube 80 may be, for example, approximately 20 μm.

The height L5 between the other one of the surfaces of the resin 90 and the other end parts 84 of the carbon nano tubes 80 can be, for example, approximately 50 μm through approximately 100 μm. Positions of the other head end parts 84 of the carbon nano tubes 80 have a designated unevenness. A relative difference L6 of positions of the head end parts 84 between the shortest carbon nano tube 80 and the longest carbon nano tube 80 may be, for example, approximately 20 μm. The entire thickness of the TIM 70 may be approximately 0.25 mm.

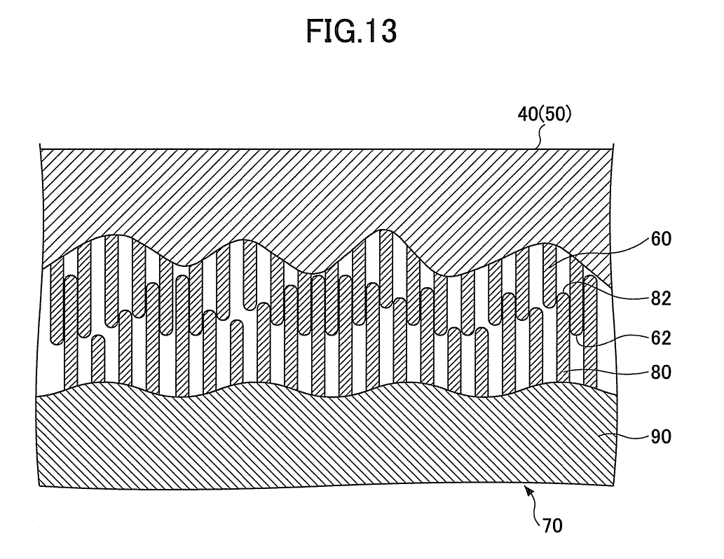

FIG. 13 is an expanded cross-sectional view of a contact part of the heat radiation plate or the heat radiation fin and the TIM shown in FIG. 12. The carbon nano tubes 60 and 80 have bending capabilities. The head end parts 62 of the carbon nano tubes 60 are positioned in a space of nm (nanometer) order formed by the neighboring carbon nano tubes 80. The head end parts 82 of the carbon nano tubes 80 are positioned in a space of nm (nanometer) order formed by the neighboring carbon nano tubes 60.

An attaching process of the heat radiator of the semiconductor package in the second embodiment is the same as that of the first embodiment shown in FIG. 8, and therefore explanation thereof is omitted.

As discussed above, in the second embodiment of the present invention, the line state carbon nano tubes 60 made of the high thermal interface material stand on a surface of the heat radiation plate 40 or the heat radiation fin 50 facing the TIM 70 in a thermally conductive direction, namely a direction perpendicular to the surface of the heat radiation plate 40 or the heat radiation fin 50 facing the TIM 70. In addition, the line state carbon nano tubes 80 made of the high thermal interface material stand on a surface of the heat radiation plate 40 or the heat radiation fin 50 facing the TIM 70 in a thermally conductive direction, namely a direction perpendicular to the surface of the heat radiation plate 40 or the heat radiation fin 50 facing the TIM 70. Thus, the carbon nano tubes 60 and the carbon nano tubes 80 are provided so as to face each other. When pressing is applied in the thermally conductive direction, the head end parts 62 of the carbon nano tubes 60 are positioned in a space of nm (nanometer) order formed by the neighboring carbon nano tubes 80. The head end parts 82 of the carbon nano tubes 80 are positioned in a space of nm (nanometer) order formed by the neighboring carbon nano tubes 60. As a result of this, since the carbon nano tubes 60 and the carbon nano tubes 80 are adhered to each other, it is possible to reduce the contact thermal resistance and improve the thermal conductivity. Therefore, it is possible to improve the heat radiating capabilities whereby the heat generated from the semiconductor element 20 is radiated to an outside.

In addition, the contact thermal resistance can be reduced without depending on surface configurations (concavities and convexities of the surface) of the heat radiation plate 40, the heat radiation fin 50 and the resin 90 and thereby the adhesion capabilities between the heat radiation plate 40 or the heat radiation fin 50 and the TIM 70 can be improved.

Even if other line state high thermal interface material (metal filler, carbon filler, graphite filler, or the like) which is the same as the carbon nano tubes 80 is used instead of the carbon nano tubes 80, the same effect can be achieved.

Thus, according to the embodiments of the present invention, it is possible to provide a heat radiator of a semiconductor package, the heat radiator having high thermal conductivity and good radiating abilities.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority or inferiority of the invention. Although the embodiments of the present invention have been described in detail, it should be understood that the various changes, substitutions, and alterations could be made hereto without departing from the spirit and scope of the invention.

What is claimed is:

1. A heat radiator of a semiconductor package, the heat radiator being provided on the semiconductor package, the heat radiator contacting a thermal interface material, the heat radiator comprising:
a line state high thermal interface material standing, in a thermally conductive direction, on a surface of the heat radiator facing the thermal interface material,
wherein head end parts of the line state high thermal interface material are adhered to a surface of the thermal interface material.

2. The heat radiator of the semiconductor package as claimed in claim 1,
wherein the line state high thermal interface material is carbon nano tubes.

3. The heat radiator of the semiconductor package as claimed in claim 1,
wherein a main ingredient of the heat radiator is oxygen-free copper.

4. A heat radiator of a semiconductor package, the heat radiator being provided on the semiconductor package, the heat radiator contacting a thermal interface material, the heat radiator comprising:
a first line state high thermal interface material standing, in a thermally conductive direction, on a surface of the heat radiator facing the thermal interface material;
a second line state high thermal interface material standing, in a thermally conductive direction, on a surface of the thermal interface material facing the heat radiator,
wherein the head end of the first line state high thermal interface material is positioned in a space formed by the neighboring second line state high thermal interface material, and the head end of the second line state high thermal interface material is positioned in a space formed by the neighboring first line state high thermal interface material, so that the head end of the first line state high thermal interface material and the head end of the second line state high thermal interface material are adhered to each other.

5. The heat radiator of the semiconductor package as claimed in claim 4,
wherein the first line state high thermal interface material is carbon nano tubes; and
the second line state high thermal interface material includes at least one of a material selected from a group consisting of a metal filler, a carbon filler, graphite, and a carbon nano tube.

6. The heat radiator of the semiconductor package as claimed in claim 4,
wherein a main ingredient of the heat radiator is oxygen-free copper.
